(19) United States
(12) Patent Application Publication
(10) Pub. No.: US 2009/0266704 A1
(43) Pub. Date: Oct. 29, 2009

(54) Sputtering Method and Sputtering Apparatus, and Electronic Device Manufacturing Method

(75) Inventor: Tadashi Hori, Fujisawa-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/428,515

(22) Filed: Apr. 23, 2009

(30) Foreign Application Priority Data
Apr. 28, 2008 (JP) 2008-117146

(51) Int. Cl. C23C 14/34

(52) U.S. Cl. 204/192.15; 204/192.12; 204/298.02

(57) ABSTRACT

A sputtering method comprising the steps of: arranging the plurality of targets in a vacuum container equidistantly in a transport direction of the substrate such that distances between the plurality of rectangular targets and the substrate are different; and assuming that lengths of sides, parallel to the transport direction, of adjacent first and second targets are expressed as first and second target width W1 and W2, respectively, and that a gap between the first and second targets is expressed as L, when a relationship among the first target width W1, the second target width W2, and the gap L satisfies L≦3(W1+W2), and assuming that a distance from each of the plurality of targets to the substrate is expressed as T, performing sputtering such that a relationship between a longest distance Tmax and the gap L at this time satisfies 0.4≦Tmax/L≦0.8.

### BACKGROUND OF THE INVENTION

1. Field of the Invention

The present invention relates to a sputtering method and sputtering apparatus for forming a film on a substrate by sputtering, and an electronic device manufacturing method to manufacture, for example, a photovoltaic element using amorphous silicon (a-Si) on a glass substrate.

2. Description of the Related Art

Conventionally, the manufacture of a photoelectric conversion device such as a solar cell and the manufacture of a flat panel display (the photoelectric conversion device and flat display panel will be generically referred to as an electronic device hereinafter) generally widely employ a sputtering apparatus. Particularly, as a method of manufacturing a solar cell, the following technique is known.

For example, in a manufacturing process for a solar cell using a non-single-crystal semiconductor film or the like, plasma CVD (Chemical Vapor Deposition) is generally employed for forming the non-single-crystal semiconductor film. Also, sputtering is widely used for forming an electrode film and put into a practical use. When the solar cell is to be manufactured, however, basically, it must have a sufficiently high photoelectric conversion efficiency and excellent characteristic stability, and must be mass-produced.

For this reason, in the manufacture of the solar cell using a non-single-crystal semiconductor film or the like, the solar cell must have higher electrical, optical, photoconductive, or mechanical characteristics, higher fatigue characteristics in repetitive use, and higher service condition characteristics. Also, the solar cell must have a larger area, and uniform film thickness and quality. In addition, such a solar cell must be mass-produced with reproducibility by high-speed deposition. These are pointed out as issues that need improvement hereafter.

In a power generation method that uses a solar cell, frequently, unit modules are connected in series or parallel with each other to form one solar cell unit, so that desired current and voltage can be obtained. Disconnection or short-circuiting should not occur in each module. Furthermore, it is important that an output voltage or output current does not vary among modules.

For these reasons, at least at the stage of fabricating the unit module, the respective layers must have ensured characteristic uniformity. The module design must be facilitated, and the module assembly must be simplified. From these viewpoints, a deposition film having excellent characteristic uniformity over a large area must be provided, so that the productivity of the solar cell is improved and its manufacturing cost is greatly reduced.

In a solar cell, semiconductor layers as the constituent elements include a semiconductor junction such as so-called pn junction or pin junction. When using a thin-film semiconductor film such as an a-Si thin-film semiconductor film, silane (SiH₄) or the like as a source gas containing an element such as phosphine (PH₃) or diborane (B₂H₆) which serves as a dopant is mixed and glow discharge decomposition is performed, thus obtaining a semiconductor film having a desired conductivity type. It is known that the semiconductor junction described above can be achieved easily by sequentially forming such semiconductor films on a desired substrate.

In an a-Si solar cell, generally, as the semiconductor layer itself has a high sheet resistance, a transparent upper electrode must be formed on the entire semiconductor surface. As such a transparent upper electrode, usually, it is indispensable to form, using a sputtering apparatus, a SnO₂ film, In₂O₃ (In₂O₃+SnO₂) film, or the like having excellent visible-light transmittance and electric conductivity. Also, a lower surface electrode must be essentially able to reflect incident light with sufficient efficiency. As the lower surface electrode, fabrication of a Ag reflecting film, an Al reflecting film, or the like by sputtering, or an oxide-based metal film (e.g., a ZnO film) which serves as an interference electrode and in which diffusion of Ag, Al, or the like is prevented is generally known. Such a solar cell has already been put into mass production.

For example, Japanese Patent Publication No. 8-26453 (to be referred to as the patent document hereinafter) discloses a sputtering apparatus which is provided with a plurality of targets to form thin alloy films. In this sputtering apparatus, three cathodes are arranged in one processing chamber. A certain type of target is attached to the central cathode. Targets of the same type which is different from the type of the target at the center are attached to the cathodes on two sides, respectively, to sandwich the central cathode. In this conventional arrangement, the central target is arranged parallel to the deposition target surface of the substrate. The targets on the two sides are inclined with respect to the deposition target surface. The distances between the respective targets and the deposition target surface and the angles of inclination of the targets on the two sides can be adjusted.

The deposition film formation method in the sputtering apparatus of the patent document described above, however, does not clearly describe the relationship between the gaps between the adjacent targets among the three targets, and the relationship among the distances between the targets and the deposition target substrate. Hence, the above patent document does not sufficiently solve the problem of space reduction of the sputtering apparatus and the problem of a high throughput including the stability of the deposition conditions.

The deposition method by sputtering using a plurality of targets is certainly suitable for semiconductor device mass production. In this deposition method, however, higher characteristic stability and uniformity, higher apparatus operation efficiency, and lower manufacturing cost are sought for, as described above, in order that thin film devices such as solar cells may gain in popularity.

To improve the photoelectric conversion efficiency and characteristic stability, a higher photoelectric conversion efficiency of the unit module is preferable, and a lower characteristic degradation rate is preferable. When the unit modules are connected in series or parallel with each other to form one solar cell unit, of the respective unit modules that constitute the solar cell unit, the unit module having a minimum current or voltage characteristics controls the performance and determines the characteristics of the solar cell unit. Therefore, it is very important to not only improve the average characteristics of each unit module but also suppress variations in the characteristics. For this reason, at the stage of fabricating the unit module, the respective deposition layers themselves must have ensured characteristic uniformity.

### SUMMARY OF THE INVENTION

The present invention has been made in consideration of the aforementioned problems, and attains a sputtering method and sputtering apparatus, and an electronic device manufacturing method which can process a substrate uniformly in a deposition processing space.

In order to solve the aforementioned problems, there is provided a method of sputtering a substrate by causing electric discharge in a vacuum container under a reduced pressure for a plurality of targets arranged to oppose the substrate, the method comprising the steps of: arranging the plurality of rectangular targets in the vacuum container equidistantly in a transport direction of the substrate such that distances between the plurality of rectangular targets and the substrate are different; and assuming that lengths of sides, parallel to the transport direction, of a first target and a second target that are adjacent, among the plurality of rectangular targets, are expressed as a first target width W1 and a second target width W2, respectively, and that a gap between a center point of the first target and a center point of the second target is expressed as L, when a relationship among the first target width W1, the second target width W2, and the gap L satisfies L≦3(W1+W2), and assuming that a distance from the center point of each of the plurality of targets to the substrate is expressed as T, performing sputtering such that a relationship between a longest distance Tmax among the distances of the plurality of targets to the substrate and the gap L at this time satisfies 0.4≦Tmax/L≦0.8.

There is also provided a sputtering apparatus for sputtering a substrate by causing electric discharge in a vacuum container under a reduced pressure for a plurality of targets arranged to oppose the substrate, wherein the plurality of targets comprise rectangular targets arranged in the vacuum container equidistantly in a transport direction of the substrate such that distances between the plurality of rectangular targets and the substrate are different, and assuming that lengths of sides, parallel to the transport direction, of a first target and a second target that are adjacent, among the plurality of rectangular targets, are expressed as a first target width W1 and a second target width W2, respectively, and that a gap between a center point of the first target and a center point of the second target is expressed as L, when a relationship among the first target width W1, the second target width W2, and the gap L satisfies L≦3(W1+W2), assuming that a distance from the center point of each of the plurality of targets to the substrate is expressed as T, a relationship between a longest distance Tmax among the distances of the plurality of targets to the substrate and the gap L at this time satisfies 0.4≦Tmax/L≦0.8.

According to the first aspect of the present invention, a plurality of targets are disposed efficiently and appropriately, so that processing variations and characteristic variations due to plasma nonuniformities that occur particularly at the center and end of a substrate can be suppressed. Therefore, according to the present invention, a substrate can be processed uniformly in the processing space.

Further features of the present invention will become apparent from the following description of exemplary embodiments with reference to the attached drawings.

### BRIEF DESCRIPTION OF THE DRAWINGS

FIG. 1 is a schematic view showing a sputtering apparatus according to the first embodiment;

FIG. 2 is a view showing the measurement result of deposition films formed by the sputtering apparatus of the first embodiment;

FIG. 3 is a schematic view showing a continuous sputtering apparatus according to the second embodiment; and

FIG. 4 is a schematic view showing an arrangement of a solar cell manufactured using the continuous sputtering apparatus of the second embodiment.

### DESCRIPTION OF THE EMBODIMENTS

Embodiments of the present invention will be described hereinafter with reference to the accompanying drawings.

### Outline of Invention

The present invention is aimed at a decreasing the space required for and increasing the throughput obtained by a sputtering apparatus which performs a deposition process, while establishing stable deposition conditions. More specifically, the present invention reached, in an arrangement in which a plurality of targets are arranged in one discharge space, an optimum relationship between gaps between the targets and among distances between the targets and a substrate.

More specifically, it is effective to use, as a substrate on which films are to be formed, a plurality of comparatively small divisional targets in one discharge space, as in the present invention, instead of using a large-size target to meet the requirements for a larger deposition target substrate. At this time, the plurality of targets are arranged such that the gaps between the center points of the respective targets and the distances between the targets and the deposition target substrate satisfy optimum relationships, respectively. As a result, a uniform, stable plasma can be generated, and a film can be formed on the deposition target substrate to maintain a uniform thickness and characteristics over a comparatively large area.

### First Embodiment

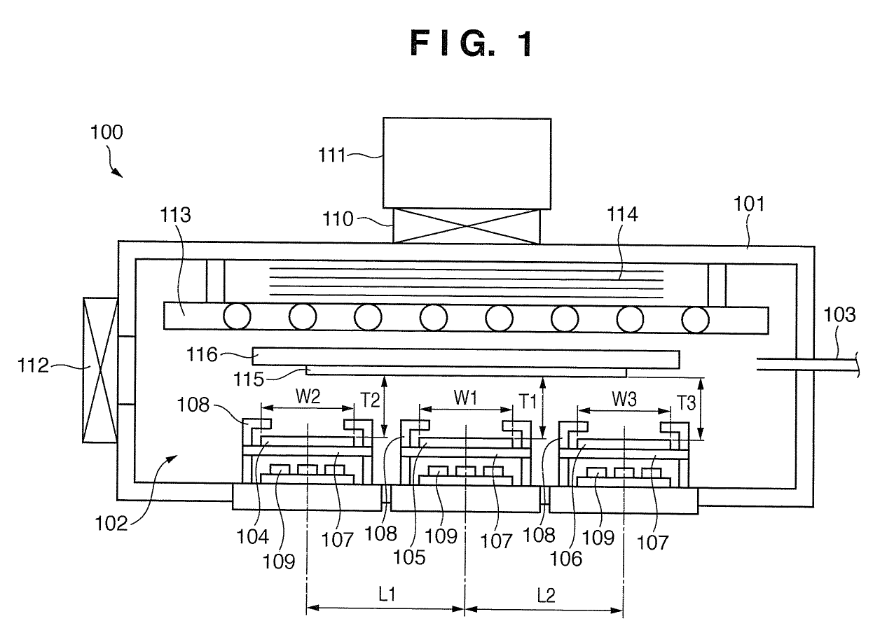

FIG. 1 is a schematic view showing an arrangement in which, as an example of a sputtering apparatus of this embodiment, three targets are arranged.

As shown in FIG. 1, a sputtering apparatus 100 includes a vacuum container 101 incorporating a processing chamber 102 serving as a processing space. First, second, and third targets 104, 105, and 106 are arranged in the processing chamber 102. A deposition target substrate 115 serving as a substrate and a substrate holder 116 for holding the deposition target substrate 115 are arranged in the processing chamber 102. The deposition target substrate 115 is transported within the processing chamber 102 in the vacuum container 101 at a predetermined speed.

The vacuum container 101 is connected to a vacuum pump 111 through an exhaust vale 110, and provided with a gas inlet port 103 and substrate inlet valve 112.

In the vacuum container 101, each of the targets 104, 105, and 106 is provided with a backing plate 107, deposition preventive plate 108, and magnet 109. A heater unit 113 which heats the deposition target substrate 115 and a heat reflecting plate 114 which reflects heat generated by the heater unit 113 are arranged in the vacuum container 101.

The first, second, and third targets 104, 105, and 106 provided to the sputtering apparatus 100 form rectangular plates, respectively, and are disposed equidistantly such that the short sides of the rectangular targets are parallel to the transport direction of the deposition target substrate 115.

A first target width W1 is the length of the first target 104 in the short side direction, that is, the length of a side parallel to the transport direction of the deposition target substrate 115. Similarly, a second target width W2 is the length of the second target 105 in the short side direction. A gap L is the distance of a straight line connecting the center point of the first target 104 and that of the second target 105. The center point of the target refers to the position of the center of the target in the short side direction and direction of thickness. A distance T1 is the distance between the first target 104 and deposition target substrate 115. Similarly, a distance T2 is the distance between the second target 105 and deposition target substrate 115, and a distance T3 is the distance between the third target 106 and deposition target substrate 115.

The relationship among the first target width W1, second target width W2, and gap L satisfies L≦3(W1+W2). When the distance from the center point of each target to the deposition target substrate is expressed as T, sputtering is performed such that the relationship between a longest distance Tmax among the distances of the plurality of targets to the deposition target substrate and the gap L at this time satisfies 0.4≦Tmax/L≦0.8. Note that L≦3(W1+W2) which indicates the relationship among the first target width W1, second target width W2, and gap L serves to define the gap L between the targets and the sizes of the respective targets within practical ranges.

Note that L≦3(W1+W2) defines the gap L between the targets disposed equidistantly. If the gap L between the targets does not satisfy L≦3(W1+W2), the targets are spaced apart by the large gap L, and the relationship 0.4≦Tmax/L≦0.8 described above cannot be established. Therefore, the gap L between the targets should satisfy L≦3(W1+W2).

Although not shown, the edge of each rectangular target is rounded by chamfering so that the area of the non-erosion portion becomes minimum. The respective targets may have different ratios of components.

When forming a film on the deposition target substrate 115 using the sputtering apparatus 100 shown in FIG. 1, before the deposition target substrate 115 is transported into the processing chamber 102, it can be heated to, for example, near the deposition temperature in a pre-processing chamber (not shown). In this case, after the deposition target substrate 115 is heated, it is transported to the processing chamber 102 while being supported by the substrate holder 116.

Using the sputtering apparatus 100 shown in FIG. 1, a transparent electrode ITO film to form an anti-reflection film for, for example, a solar cell device, was formed on a 1-m square glass substrate.

The lengths of the targets in the short side direction were equal among the first, second, and third targets 104, 105, and 106, that is, W1=W2=W3=200 mm. The gap L between the center points of the targets was set to satisfy L1=L2=500 mm. The distance T between each target and the deposition target substrate 115 was set to satisfy T1=150 mm, T2=200 mm, and T3=150 mm.

At this time, L1=L2=500≦3(W1+W2)=3(200+200)=1200 was calculated. The targets were arranged to satisfy L≦3(W1+W2). Also, the longest distance Tmax satisfies Tmax=T2=200>150=T1=T3, and Tmax/L=200/500=0.4 was calculated. Each target was arranged to satisfy 0.4≦Tmax/L≦0.8.

The deposition target substrate 115 was preheated in advance before it was loaded into the processing chamber 102, so that the operating efficiency of the sputtering apparatus 100 was raised.

After that, the deposition target substrate 115 was introduced into the processing chamber 102. As the sputtering gas, Ar gas and O₂ gas were employed. The pressure was set to 0.4 Pa. A DC power supply (not shown) supplied DC power to the backing plate 107 in order to cause electric discharge. An ITO film was deposited on the 1-m square glass substrate described above to 0.8 μm. One trial of this process took a deposition film forming time of 1 min.

This trial was consecutively repeated 300 times, and 20 samples were arbitrarily extracted. The film thickness and sheet resistance of each sample were measured at 45 points that equally divided the deposition target substrate 115 with reference to a position inside the edge of the deposition target substrate 115 by 20 mm. As a result, in each measurement item, the maximum difference between the measurement point at the edge and that at the center of the deposition target substrate 115 was 3.5% or less, and 1% or less among different samples.

Using the sputtering apparatus 100 shown in FIG. 1, an Ag film was deposited at a thickness of 0.2 μm on a 1-m square glass substrate. In this deposition, a rectangular target with 100 mm short sides in a direction parallel to the transport direction was used. Under the condition that the distances T between the respective targets and the glass substrate as the deposition target substrate 115 were fixed to satisfy T1=T2=T3=200 mm, sputtering was performed while changing the gaps L between the targets and the glass substrate L from 550 mm to 200 mm every 50 mm such that L1=L2=L3 was satisfied.

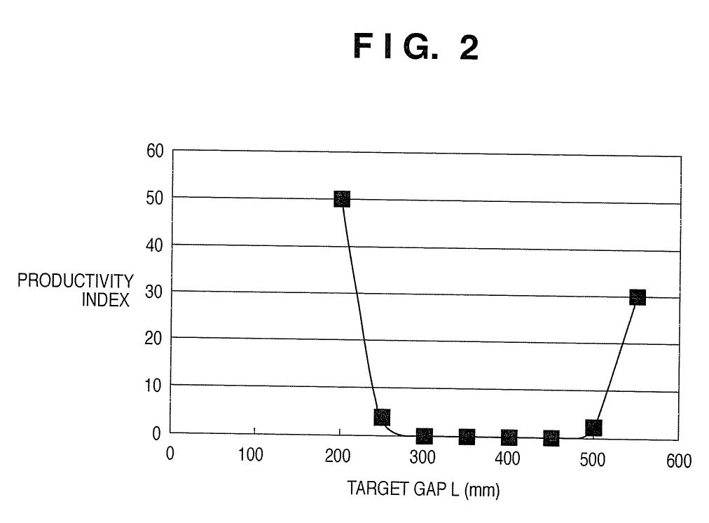

This trial was consecutively repeated 100 times for each distance relationship. Using 10 arbitrarily extracted glass substrates, the index range where the sputtering apparatus operated stably and the uniform film formation was possible was obtained. As the index, the product of the number of occurrences of abnormal charge during film formation in the trial under the positional relationship (gap) of each target and the film thickness distribution obtained when the film thickness was measured at 25 points per glass substrate was obtained in the form of a relationship. FIG. 2 shows the result. In FIG. 2, the axis of ordinate represents the productivity index as a value calculated from the product of the number of occurrences of abnormal charge and the value of the film thickness distribution obtained by measuring the film thickness at 25 points per glass substrate. The axis of abscissa represents the gap L between the targets. When the productivity index plotted along the axis of ordinate has a smaller value, discharge becomes more stable, and uniform film formation is possible.

As shown in FIG. 2, the value of the productivity index changed sharply when the gap L between the center points of the targets was between 550 mm and 500 mm, and between 200 mm and 250 mm. Accordingly, the gap L between the center points of the targets preferably falls within a range of 250 mm to 500 mm. Within this range, discharge was stable, and film formation was able to be performed with a uniform film thickness distribution. From this result, since Tmax=T1=T2=T3=200 mm, 0.4≦Tmax/L≦0.8 was established.

### Second Embodiment

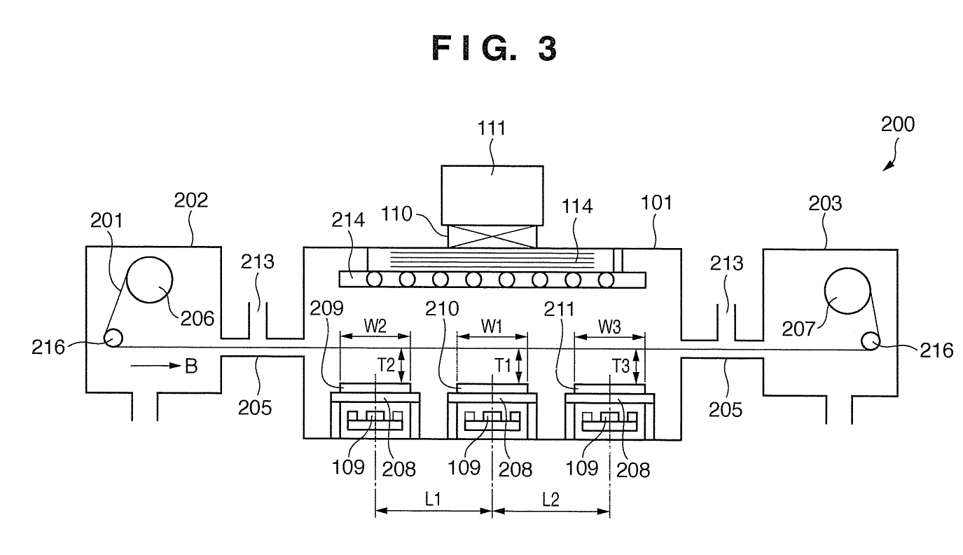

A continuous sputtering apparatus employing a roll-to-roll method will be described as the second embodiment. FIG. 3 shows a schematic view of the continuous sputtering apparatus of this embodiment. In the second embodiment, the same members as those of the first embodiment described above are denoted by the same reference numerals for the sake of convenience, and a repetitive description will be omitted.

As shown in FIG. 3, a continuous sputtering apparatus 200 of this embodiment continuously sputters a band-like substrate 201 as a belt-like long substrate. In the continuous sputtering apparatus 200, a vacuum container 101 is connected to a feed container 202 and take-up container 203 for the band-like substrate 201 through gas gates 205.

The feed container 202 has a feed bobbin 206 for feeding the band-like substrate 201. The take-up container 203 has a take-up bobbin 207 for taking up the band-like substrate 201. In each of the feed container 202 and take-up container 203, a transport roller 216 which transports the band-like substrate 201 is arranged on the transport path for the band-like substrate 201. The transport roller 216 also serves as a mechanism that adjusts the tension of the band-like substrate 201 and positions the band-like substrate 201. The feed bobbin 206 and take-up bobbin 207 transport the band-like substrate 201 in the direction of an arrow B in FIG. 3.

In the continuous sputtering apparatus 200, the feed bobbin 206 and take-up bobbin 207 are rotated in the opposite direction where necessary, so the band-like substrate 201 can be transported in a direction opposite to the direction of the arrow B. A take-up mechanism for a protection sheet such as a slit sheet used to protect the surface of the band-like substrate 201, and a protection sheet feed mechanism may be arranged in the feed container 202 and take-up container 203, respectively. As the material of the slit sheet, a polyimide-based material, polytetrafluoroethylene-based material, glass-wool-based material, or the like which is a heat-resistant resin is preferably employed.

In the vacuum container 101, a heater unit 214 is arranged at a position opposing respective targets 209, 210, and 211 through the band-like substrate 201. In the vacuum container 101, the targets 209, 210, and 211 respectively supported by backing plates 208 connected to a DC power supply (not shown) oppose the band-like substrate 201.

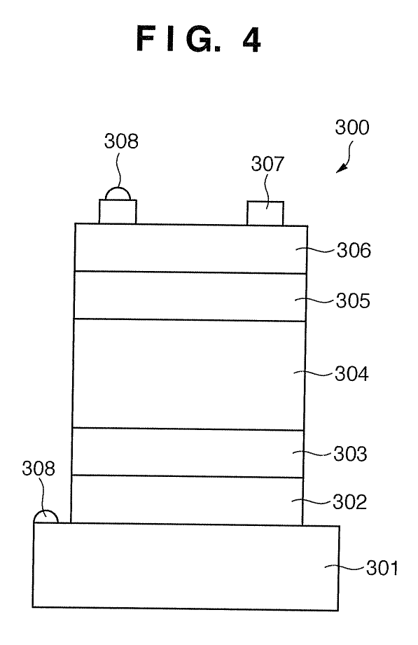

Using the continuous sputtering apparatus 200 of the embodiment shown in FIG. 3, a solar cell as shown in FIG. 4 was continuously fabricated. As shown in FIG. 4, a solar cell 300 as an electronic device is obtained by forming a lower electrode 302, n-type semiconductor layer 303, i-type semiconductor layer 304, p-type semiconductor layer 305, and transparent electrode 306 on a conductive substrate 301 in the order named. The conductive substrate 301 and transparent electrode 306 are provided with output electrodes 308, respectively. The transparent electrode 306 is provided with a collecting electrode 307.

### Electronic Device Manufacturing Method

A method of manufacturing a solar cell as an electronic device will be described hereinafter.

The band-like substrate 201 (300 mm (width)×1,100 m (length)×0.2 mm (thickness)) made of SUS430BA according to the JIS standards (Japanese Industrial Standards), which was sufficiently degreased and cleaned was wound around the feed bobbin 206. This feed bobbin 206 was set in the feed container 202. Subsequently, the band-like substrate 201 was guided to the take-up container 203 through the gas gates 205, and its tension was adjusted to such a degree that the band-like substrate 201 would not slack. A vacuum pump 111 evacuated the containers 202 and 203 to 5×10E−5 Pa or less and set them under a reduced pressure.

Ar gas was introduced as the gate gas to the gas gates 205 from gate gas inlet pipes 213 at a flow rate of 50 atm·cc/min (8.3×10⁻⁴ L/s). The Ar gas was introduced to the vacuum container 101 through the gas gates 205 at a flow rate of 200 atm·cc/min (3.3×10⁻³ L/s), so that the internal pressure of the vacuum container 101 became 0.4 Pa. The heater unit 214 heated the band-like substrate 201 and the wall surface of the vacuum container 101 to 300° C. The vacuum container 101 was left to stand still in this state for 2 hr.

After that, the vacuum pump 111 evacuated the containers 202, 203, and 204 to 1×10E−5. Then, Ar gas was introduced as the gate gas to the gas gates 205 from the gate gas inlet pipes 213 at a flow rate of 100 atm·cc/min (1.7×10⁻³ L/s). The Ar gas was introduced to the vacuum container 101 through the gas gates 205 at a flow rate of 180 atm·cc/min (3.0×10⁻³ L/s). This adjusted the internal pressure of the vacuum container 101 to 0.4 Pa.

Then, the heater unit 214 was set at a temperature of 200° C. Subsequently, the output value of the DC power supply (not shown) was set to be 50 kW, 40 kW, and 50 kW for the first, second, and third targets 209, 210, and 211, respectively, to cause discharge in the vacuum container 101. After checking the stability of the discharge of about 10 min, magnets 109 were started to swing. In this case, the length of the target in the short side direction was 300 mm in each of the first, second, and third targets 209, 210, and 211. Also, a gap L between the targets was set to satisfy L1=L2=500 mm. The distance T between each target and the band-like substrate 201 was set to satisfy T1=150 mm, T2=200 mm, and T3=150 mm. Hence, each target satisfied L≦3(W1+W2). At this time, each target was arranged to satisfy 0.4≦Tmax/L≦0.8.

The band-like substrate 201 was transported in the direction of the arrow B in FIG. 3 at a transport rate of 2,000 mm/min. As the lower electrode 302, an Al thin film was continuously formed to a thickness of 100 nm by the sputtering method of this embodiment.

After the band-like substrate 201 was transported by a length corresponding to one roll, every plasma and every gas supply were stopped, power supply to the heater unit 214 was entirely stopped, and transport of the band-like substrate 201 was stopped. Then, N₂ gas for the vacuum container leakage was introduced into every vacuum container 101 through an inlet member (not shown). The vacuum container 101 was left to stand still at 1,000 Pa until it was cooled sufficiently, and restored to the atmospheric pressure. Then, the band-like substrate 201 taken up by the take-up bobbin 207 was taken out.

Using a roll-to-roll type CVD apparatus, an n-type semiconductor layer, p-type a-Si semiconductor layer, and i-type μc-Si semiconductor layer were formed on the band-like substrate 201 on which the lower electrode 302 had been fabricated.

Using the continuous sputtering apparatus 200 shown in FIG. 3, an ITO (In₂O₃+SnO₂) film was formed as the transparent electrode 306 on the p-type semiconductor layer of the band-like substrate 201. As the film formation gas, Ar gas had a flow rate of 180 atm·cc/min (3.0×10⁻³ L/s), and O₂ gas had a flow rate of 20 atm·cc/min (3.3×10⁻⁴ L/s). The distance T between each target and the band-like substrate 201 was set to satisfy T1=T2=T3=150 mm. Other than this, the conditions were the same as those for the deposition method for the lower electrode Al described above.

After taking out the band-like substrate 201, it was cut into pieces at pitches of 200 mm. As the collecting electrode 307, Ag was deposited on each piece to a thickness of 3 μm by vacuum deposition. Thus, the solar cell 300 shown in FIG. 4 was fabricated.

The fabricated solar cell 300 was evaluated concerning photoelectric conversion efficiency η={maximum generated power per unit area (mW/cm²)/incident light intensity per unit area (mW/cm²)}. Sampling inspection was performed by disposing every 10 m of the band-like substrate 201 as a measurement sample under light irradiation with AM-1.5 (pseudo solar light) of an irradiation device at an irradiation intensity of 100 mW/cm². The open voltage, filter factor, and photoelectric conversion efficiency η were evaluated by applying a DC voltage to the output electrodes 308 of the solar cell 300 and measuring the current-voltage characteristics.

As a result, regarding the characteristics of 100 solar cells, variations of the value of the open voltage, the value of the filter factor, and the photoelectric conversion efficiency η fell within ranges of ±3%, ±2%, and ±1%, respectively. Thus, the solar cell had stable cell characteristics even in the second half of deposition.

As has been described above, according to this embodiment, deformation in shape of the deposition target substrate in a processing space is suppressed. During the substrate processing procedure, processing nonuniformities and characteristic nonuniformities caused by nonuniformities in shape particularly at the center and end of the deposition target substrate can be suppressed. This enables uniform processing in the processing space. This embodiment can realize production facilities with high uniformity and reproducibility in the device characteristics of an electronic device particularly such as a solar cell or FDP.

According to this embodiment, in the manufacture of particularly a solar cell or the like, even when forming a sputtering film on a microcrystal semiconductor layer under strict deposition conditions, the process can be performed without inducing abnormal discharge that influences the semiconductor device itself. Therefore, this embodiment leads to an increase in operation efficiency of the sputtering apparatus and furthermore an improvement of the yield, thus realizing production facilities requiring a low production cost.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-117146, filed Apr. 28, 2008, which is hereby incorporated by reference herein in its entirety.

What is claimed is:

1. A method of sputtering a substrate by causing electric discharge in a vacuum container under a reduced pressure for a plurality of targets arranged to oppose the substrate, the method comprising the steps of:
arranging the plurality of rectangular targets in the vacuum container equidistantly in a transport direction of the substrate such that distances between the plurality of rectangular targets and the substrate are different; and
assuming that lengths of sides, parallel to the transport direction, of a first target and a second target that are adjacent, among the plurality of rectangular targets, are expressed as a first target width W1 and a second target width W2, respectively, and that a gap between a center point of the first target and a center point of the second target is expressed as L, when a relationship among the first target width W1, the second target width W2, and the gap L satisfies L≦3(W1+W2), and
assuming that a distance from the center point of each of the plurality of targets to the substrate is expressed as T, performing sputtering such that a relationship between a longest distance Tmax among the distances of the plurality of targets to the substrate and the gap L at this time satisfies 0.4≦Tmax/L≦0.8.

2. The method according to claim 1, wherein the plurality of targets have different ratios of components.

3. The method according to claim 1, wherein the substrate forms a long band and is transported continuously in the vacuum container.

4. A sputtering apparatus for sputtering a substrate by causing electric discharge in a vacuum container under a reduced pressure for a plurality of targets arranged to oppose the substrate, wherein
the plurality of targets comprise rectangular targets arranged in the vacuum container equidistantly in a transport direction of the substrate such that distances between the plurality of rectangular targets and the substrate are different, and
assuming that lengths of sides, parallel to the transport direction, of a first target and a second target that are adjacent, among the plurality of rectangular targets, are expressed as a first target width W1 and a second target width W2, respectively, and that a gap between a center point of the first target and a center point of the second target is expressed as L, when a relationship among the first target width W1, the second target width W2, and the gap L satisfies L≦3(W1+W2),
assuming that a distance from the center point of each of the plurality of targets to the substrate is expressed as T, a relationship between a longest distance Tmax among the distances of the plurality of targets to the substrate and the gap L at this time satisfies 0.4≦Tmax/L≦0.8.

5. The apparatus according to claim 4, wherein the plurality of targets have different ratios of components.

6. The apparatus according to claim 4, wherein the substrate forms a long band and is transported continuously in the vacuum container.

7. An electronic device manufacturing method of forming an electronic device by forming a film on a substrate using a sputtering apparatus according to claim 4.
